(19) United States
(12) Patent Application Publication
(10) Pub. No.: US 2023/0249283 A1
(43) Pub. Date: Aug. 10, 2023

(54) PROCESSING SYSTEM

(71) Applicant: DISCO CORPORATION, Tokyo (JP)

(72) Inventors: Keiichiro NIITSU, Tokyo (JP); Youngsuk KIM, Tokyo (JP); Koji WATANABE, Tokyo (JP)

(21) Appl. No.: 18/159,716

(22) Filed: Jan. 26, 2023

(30) Foreign Application Priority Data
Feb. 9, 2022 (JP) 2022-018640

(51) Int. Cl. B23K 26/00; B24B 7/22; B23K 26/06; B23K 26/50

(52) U.S. Cl. CPC B23K 26/0093; B24B 7/228; B23K 26/0648; B23K 26/0626; B23K 26/50

(57) ABSTRACT

A grinding apparatus conveys a wafer from a first rough grinding unit and a first finish grinding unit to a first laser beam irradiation unit by a turntable. Thus, in one grinding apparatus, the wafer can be ground and damage of the wafer caused due to the grinding can be repaired easily and rapidly. Therefore, it is possible to execute the grinding of the wafer and the repair of the damage efficiently and favorably.

### BACKGROUND OF THE INVENTION

### Field of the Invention

The present invention relates to a processing system that thins a workpiece.

### Description of the Related Art

It is general that, after a workpiece is ground, polishing by a polishing pad is executed in order to planarize a surface and eliminate recesses and projections thereof and remove grinding marks and damage due to the grinding as disclosed in Japanese Patent Laid-open No. 2005-153090.

### SUMMARY OF THE INVENTION

Thus, an object of the present invention is to provide a processing system that can planarize a ground surface and remove at least part of damage due to grinding after the grinding.

In accordance with an aspect of the present invention, there is provided a processing system of a workpiece. The processing system includes a grinding unit that includes a grinding wheel and a spindle that rotatably supports the grinding wheel, and grinds the workpiece, an energy supply unit that supplies energy to a ground surface of the workpiece ground by the grinding unit and melts the ground surface to repair at least part of damage caused due to the grinding, and a conveying unit that conveys the workpiece from the grinding unit to the energy supply unit.

Preferably, the energy supply unit is a laser beam irradiation unit that includes a laser oscillator that emits a laser beam and a condenser lens that condenses the laser beam, and executes irradiation with the laser beam.

Preferably, the laser beam irradiation unit executes irradiation with the laser beam with a wavelength having absorbability with respect to the workpiece. Preferably, the wavelength of the laser beam is a wavelength in a range of 500 to 1000 nm.

Preferably, the conveying unit is a turntable that rotatably supports a holding table that holds the workpiece, and the holding table that holds the workpiece is moved from the grinding unit to the energy supply unit by rotation of the turntable.

In this processing system, the energy is supplied to the ground surface of the workpiece and the ground surface including the damage caused due to the grinding is melted. Therefore, the ground surface can be planarized. In addition, it becomes possible to repair at least part of the damage caused in the ground surface. Furthermore, in the case of the laser beam, it is also possible to melt not only the ground surface but also a part in the vicinity of the ground surface and repair damage thereof by setting the wavelength to the wavelength having absorbability with respect to the workpiece.

Furthermore, by the energy supply unit, through melting of a superficial layer of the ground surface by supply of the energy and subsequent resolidification of the superficial layer of the cooled ground surface, at least part of the damage is repaired and the ground surface is planarized. Thus, unlike grinding and polishing in which processing is executed while part of a superficial layer of a workpiece is removed, processing dust is not generated, and there is no possibility of adhesion of the processing dust to the workpiece and a processing chamber.

Moreover, in the case of using the laser beam irradiation unit as the energy supply unit, a treatment of a waste liquid is unnecessary and the facility can be simplified because processing by the laser beam is processing in which water is not used.

Furthermore, in this processing system, the workpiece can be conveyed from the grinding unit to the energy supply unit by the conveying unit. Thus, in the one system, the workpiece can be ground by the grinding unit and the damage of the workpiece caused due to the grinding can be repaired easily and rapidly by the energy supply unit. Therefore, it is possible to execute the grinding of the workpiece and the repair of the damage efficiently and favorably.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a plan view illustrating the configuration of a grinding apparatus that is one example of a processing system;

FIG. 2 is a perspective view illustrating the configuration of a first rough grinding unit and a first finish grinding unit;

FIG. 3 is a sectional view illustrating the configuration of the first rough grinding unit and the first finish grinding unit;

FIG. 4 is a perspective view illustrating the configuration of a first laser beam irradiation unit;

FIG. 5 is a schematic diagram illustrating the configuration of the first laser beam irradiation unit;

FIG. 6 is a plan view illustrating an example of an energy supply step;

FIG. 7 is a plan view illustrating another processing system;

FIG. 8 is a perspective view illustrating the configuration of a second laser beam irradiation unit;

FIG. 9 is a plan view illustrating another example of the energy supply step;

FIG. 10 is a perspective view illustrating an example of a conveying system; and

FIG. 11 is a table indicting a relation between a wavelength of a laser beam emitted from a laser oscillator and a result of the energy supply step executed by using each laser beam.

### DETAILED DESCRIPTION OF THE PREFERRED EMBODIMENT

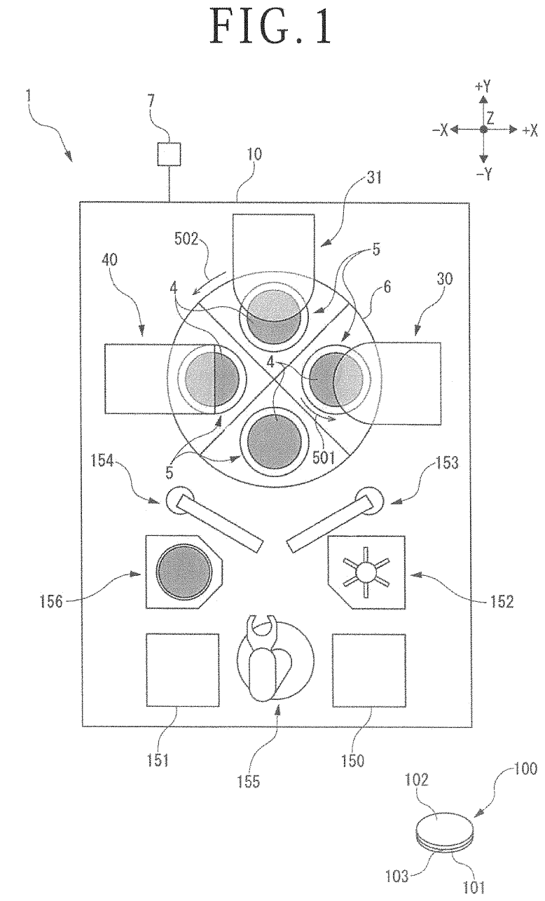

A grinding apparatus 1 illustrated in FIG. 1 is one example of a processing system and includes holding tables 5 that hold a wafer 100, a first rough grinding unit 30, and a first finish grinding unit 31. In the grinding apparatus 1, the wafer 100 held by each holding table 5 is ground by the first rough grinding unit 30 and the first finish grinding unit 31.

The wafer 100 illustrated in FIG. 1 is one example of a workpiece and is a circular semiconductor wafer, for example. Devices that are not illustrated are formed on a front surface 101 of the wafer 100. The front surface 101 of the wafer 100 is oriented downward in FIG. 1 and is protected by sticking of a protective tape 103 thereto. A grinding treatment is executed for a back surface 102 of the wafer 100.

The grinding apparatus 1 includes an apparatus base 10 and a first controller 7 that controls the respective components of the grinding apparatus 1.

A first cassette 150 and a second cassette 151 are disposed on the front side (−Y direction side) of the apparatus base 10. The first cassette 150 and the second cassette 151 internally include plural shelves and one wafer 100 is housed in each shelf.

A robot hand 155 is disposed near openings (not illustrated) of the first cassette 150 and the second cassette 151. The robot hand 155 carries in the wafer 100 after processing to the first cassette 150 or the second cassette 151. Furthermore, the robot hand 155 takes out the wafer 100 before processing from the first cassette 150 or the second cassette 151 and places it over a temporary placement unit 152.

The wafer 100 placed over the temporary placement unit 152 is placed over a holding surface 4 of the holding table 5 near the temporary placement unit 152 by a carrying-in unit 153.

The holding table 5 includes the holding surface 4 for holding the wafer 100. The holding surface 4 is made to communicate with a suction source that is not illustrated, and can suck and hold the wafer 100 with the interposition of the protective tape 103.

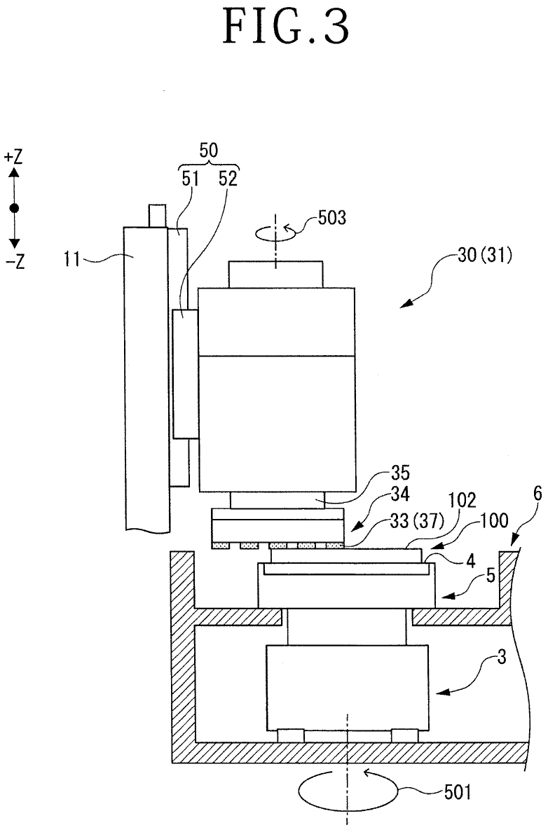

Furthermore, by a table rotation-support mechanism 3 illustrated in FIG. 3, the holding table 5 can rotate in a direction of an arrow 501, for example, around a center axis that passes through the center of the holding surface 4 and extends in a Z-axis direction in the state in which the holding table 5 holds the wafer 100 by the holding surface 4.

In the present embodiment, as illustrated in FIG. 1, on the upper surface of a turntable 6 disposed on the apparatus base 10, four holding tables 5 are disposed at equal intervals in a circumferential direction. The turntable 6 rotatably supports the holding tables 5 that hold the wafer 100. Furthermore, the turntable 6 moves the holding tables 5 that hold the wafer 100 among the first rough grinding unit 30, the first finish grinding unit 31, and a first laser beam irradiation unit 40.

A rotating shaft that is for causing the turntable 6 to rotate and is not illustrated is disposed at the center of the turntable 6. By this rotating shaft, the turntable 6 can rotate in a direction of an arrow 502, for example, around the axial center extending in the Z-axis direction. Due to the rotation of the turntable 6, the four holding tables 5 are revolved. This allows the turntable 6 to sequentially position the holding tables 5 that support the wafer 100 to the vicinity of the temporary placement unit 152, the lower side of the first rough grinding unit 30, the lower side of the first finish grinding unit 31, and the lower side of the first laser beam irradiation unit 40.

As above, the turntable 6 is one example of a conveying unit that conveys the wafer 100 from the first rough grinding unit 30 and the first finish grinding unit 31 to the first laser beam irradiation unit 40. That is, in the present embodiment, by rotation of the turntable 6, the holding tables 5 that hold the wafer 100 are moved from the first rough grinding unit 30 and the first finish grinding unit 31 to the first laser beam irradiation unit 40.

The wafer 100 placed over the holding surface 4 of the holding table 5 by the carrying-in unit 153 is first positioned to the lower side of the first rough grinding unit 30 illustrated in FIG. 1 by rotation of the turntable 6. The first rough grinding unit 30 is one example of a grinding unit that grinds the wafer 100.

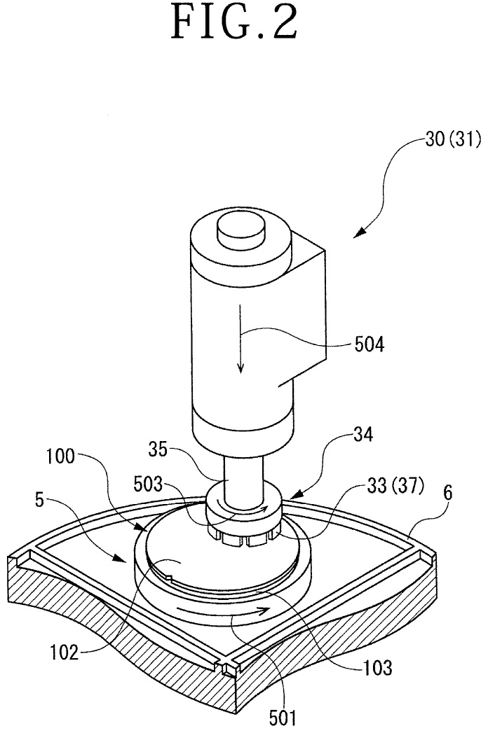

As illustrated in FIG. 2, the first rough grinding unit 30 includes a grinding wheel 34 having rough grinding abrasive stones 33 and a spindle 35 that rotatably supports the grinding wheel 34. As illustrated in FIG. 2, the first rough grinding unit 30 is configured to execute rough grinding of the wafer 100 held by the holding table 5 that rotates by the rough grinding abrasive stones 33 of the grinding wheel 34 by lowering the first rough grinding unit 30 as illustrated by an arrow 504 while rotating the grinding wheel 34 as illustrated by an arrow 503.

Furthermore, as illustrated in FIG. 3, the first rough grinding unit 30 is mounted to a column 11 erected on the apparatus base 10 (see FIG. 1) with the interposition of a vertical movement unit 50. The vertical movement unit 50 holds the first rough grinding unit 30 and moves the first rough grinding unit 30 in the vertical direction (Z-axis direction) relative to the holding table 5.

The vertical movement unit 50 includes a Z-axis guide rail 51 extending in the Z-axis direction and a holding plate 52 that slides on this Z-axis guide rail 51. The holding plate 52 holds the first rough grinding unit 30.

In the vertical movement unit 50, the holding plate 52 moves in the Z-axis direction along the Z-axis guide rail 51 by a driving force of a motor that is not illustrated. Thereby, the first rough grinding unit 30 held by the holding plate 52 and the grinding wheel 34 included in the first rough grinding unit 30 move in the Z-axis direction together with the holding plate 52.

After the rough grinding by the first rough grinding unit 30, the wafer 100 is positioned to the lower side of the first finish grinding unit 31 illustrated in FIG. 1 by rotation of the turntable 6. The first finish grinding unit 31 is one example of the grinding unit that grinds the wafer 100 held by the holding table 5 and is mounted to the column 11 erected on the apparatus base 10, for example. As illustrated in FIG. 2 and FIG. 3, the first finish grinding unit 31 has a configuration similar to that of the first rough grinding unit 30 except for having finish grinding abrasive stones 37 instead of the rough grinding abrasive stones 33.

Furthermore, as illustrated in FIG. 3, the grinding apparatus 1 includes the vertical movement unit 50 that has a configuration similar to that of what is for moving the first rough grinding unit 30, and is for moving the first finish grinding unit 31.

After the finish grinding by the first finish grinding unit 31, the wafer 100 is positioned to the lower side of the first laser beam irradiation unit 40 illustrated in FIG. 1 by rotation of the turntable 6.

The first laser beam irradiation unit 40 is one example of an energy supply unit that supplies energy to a ground surface of the wafer 100 ground by the first rough grinding unit 30 and the first finish grinding unit 31 and melts the ground surface to repair at least part of damage caused by the grinding.

In the present embodiment, the energy supply unit will be described as a laser beam irradiation unit. However, the energy supply unit is not limited thereto and may be a plasma etching apparatus that supplies plasma or an apparatus that supplies electromagnetic waves or an ion beam.

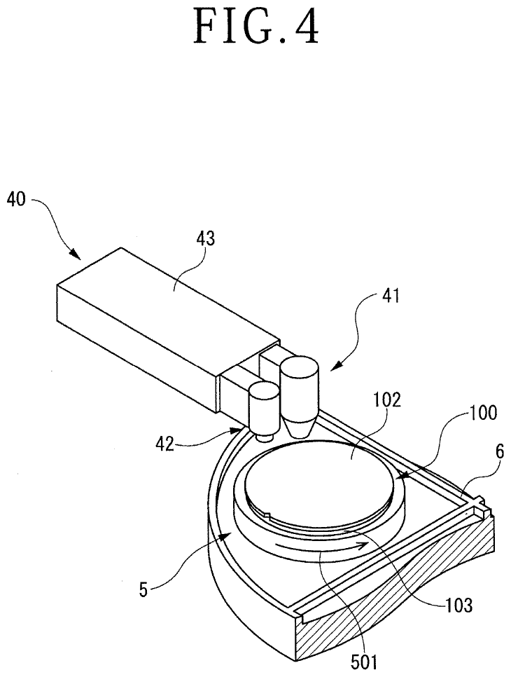

The first laser beam irradiation unit 40 irradiates a ground surface of the wafer 100 ground by the first rough grinding unit 30 and the first finish grinding unit 31 with a laser beam and melts the ground surface to repair at least part of damage caused by the grinding. As illustrated in FIG. 4, the first laser beam irradiation unit 40 has a processing head (light condenser) 41 for irradiating the wafer 100 with the laser beam, a camera 42 that images the ground surface of the wafer 100, and a casing 43 that supports them. The configuration of the first laser beam irradiation unit 40 will be described later.

After the irradiation with the laser beam, the wafer 100 is conveyed to a first cleaning unit 156 by a carrying-out unit 154 illustrated in FIG. 1 and is cleaned. The cleaned wafer 100 is carried in to the first cassette 150 or the second cassette 151 (cassette from which the wafer 100 has been taken out) by the robot hand 155.

The first controller 7 includes a central processing unit (CPU) that executes calculation processing according to a control program, a storage medium such as a memory, and so forth. The first controller 7 controls the respective components of the grinding apparatus 1 to execute grinding processing for the wafer 100. A processing method of the wafer 100 in the grinding apparatus 1 on the basis of control by the first controller 7 will be described below.

(1) Holding Step

In processing of the wafer 100, first, the first controller 7 controls the robot hand 155 illustrated in FIG. 1 to take out the wafer 100 before processing from, for example, the first cassette 150 and place it over the temporary placement unit 152. Moreover, the first controller 7 controls the carrying-in unit 153 to hold the wafer 100 over the temporary placement unit 152 and place it over the holding surface 4 of the holding table 5 with the back surface 102 being the upper surface. Thereafter, the first controller 7 causes the holding surface 4 to communicate with the suction source that is not illustrated. This causes the holding surface 4 to suck and hold the wafer 100 with the interposition of the protective tape 103. In this way, the wafer 100 is held by the holding table 5.

(2) Grinding Step

In this step, the first rough grinding unit 30 and the first finish grinding unit 31 grind the wafer 100 held by the holding table 5.

(2-1) Rough Grinding Step

After the holding step, the first controller 7 rotates the turntable 6 illustrated in FIG. 1 to dispose the holding table 5 that holds the wafer 100 to the lower side of the first rough grinding unit 30.

Then, the first controller 7 rotates the grinding wheel 34 of the first rough grinding unit 30 and executes grinding feed of the first rough grinding unit 30 along the Z-axis direction by the vertical movement unit 50 (see FIG. 3). Moreover, the first controller 7 rotates the holding table 5 by the table rotation-support mechanism 3.

This causes the rough grinding abrasive stones 33 of the rotating grinding wheel 34 to get contact with the back surface 102 of the wafer 100 held by the rotating holding table 5 and execute rough grinding of the back surface 102.

In the grinding by the rough grinding abrasive stones 33, the first controller 7 measures a thickness of the wafer 100 by using a thickness measuring instrument that is not illustrated. Furthermore, the first controller 7 executes the grinding by the rough grinding abrasive stones 33 until the thickness of the wafer 100 becomes a predetermined rough grinding thickness.

(2-2) Finish Grinding Step

In a finish grinding step, finish grinding of the surface ground by the rough grinding abrasive stones 33 in the wafer 100 is executed. In this step, first, the first controller 7 rotates the turntable 6 illustrated in FIG. 1 to dispose the holding table 5 that holds the wafer 100 to the lower side of the first finish grinding unit 31.

Then, similarly to the rough grinding step, the first controller 7 rotates the grinding wheel 34 and executes grinding feed of the first finish grinding unit 31 along the Z-axis direction by the vertical movement unit 50. Moreover, the first controller 7 rotates the holding table 5 by the table rotation-support mechanism 3.

This causes the finish grinding abrasive stones 37 of the rotating grinding wheel 34 to get contact with the back surface 102 of the wafer 100 held by the rotating holding table 5 and execute finish grinding of the back surface 102.

In the grinding by the finish grinding abrasive stones 37, the first controller 7 measures the thickness of the wafer 100 by using a thickness measuring instrument that is not illustrated. Furthermore, the first controller 7 executes the grinding by the finish grinding abrasive stones 37 until the thickness of the wafer 100 becomes a predetermined finish grinding thickness.

(3) Energy Supply Step

In this step, the first laser beam irradiation unit 40 melts the back surface 102 that is the ground surface of the wafer 100 through irradiation with the laser beam and then cools and recrystallizes the back surface 102 to repair at least part of damage caused by the grinding. Furthermore, there is also an effect that the ground surface is planarized due to the melting and resolidification. This damage (damage layer) is a processing alteration part (processing alteration layer) including cracks, scratches, chips, and so forth caused by the grinding, for example.

Here, the configuration of the first laser beam irradiation unit 40 will be described. The first laser beam irradiation unit 40 includes at least a laser oscillator that emits the laser beam and a condenser lens that condenses the laser beam, and emits the laser beam with a wavelength having absorbability with respect to the wafer 100 that is a workpiece.

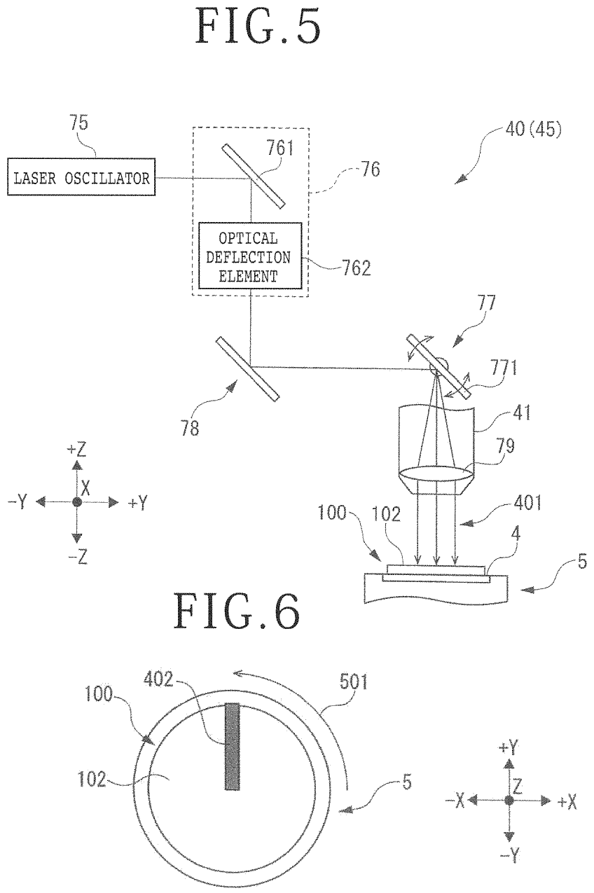

As illustrated in FIG. 5, the first laser beam irradiation unit 40 includes a laser oscillator 75 that emits the laser beam, an X-axis direction disperser 76, and a resonant scanner 77 in addition to the above-described processing head 41 having the condenser lens. These laser oscillator 75, X-axis direction disperser 76, resonant scanner 77, and so forth are disposed in the casing 43 and the processing head 41 of the first laser beam irradiation unit 40 illustrated in FIG. 4.

The laser oscillator 75 emits the laser beam with a wavelength having absorbability with respect to the wafer 100. The X-axis direction disperser 76 has an optical deflection element (acousto-optic deflector (AOD)) 762 and a first mirror 761 that guides the laser beam from the laser oscillator 75 to the optical deflection element 762, and adjusts the position in an X-axis direction regarding the laser beam emitted from the laser oscillator 75. The laser beam from the X-axis direction disperser 76 is guided to the resonant scanner 77 through a second mirror 78.

The resonant scanner 77 includes a swing mirror 771 that reflects incident light and can swing, and reciprocates the irradiation position (optical path) of the laser beam along a Y-axis direction. The resonant scanner 77 can reciprocate the irradiation position of the laser beam along the Y-axis direction with any frequency and deflection angle by controlling swing motion of the swing mirror 771.

The laser beam from the resonant scanner 77 is guided to an fθ lens 79 in the processing head 41. The fθ lens 79 is the condenser lens that condenses the laser beam. The fθ lens 79 converts the laser beam from the resonant scanner 77 to a collimated laser beam 401 with an equal focal height and applies the laser beam 401 onto the back surface 102 that is the ground surface of the wafer 100 held by the holding surface 4 of the holding table 5.

The first controller 7 executes an energy supply step by using the first laser beam irradiation unit 40 having such a configuration.

Specifically, first, the first controller 7 rotates the turntable 6 illustrated in FIG. 1 to dispose the holding table 5 that holds the wafer 100 to the lower side of the first laser beam irradiation unit 40.

Next, the first controller 7 causes emission of the laser beam from the laser oscillator 75 and controls the swing state of the swing mirror 771 in the resonant scanner 77 in the first laser beam irradiation unit 40 illustrated in FIG. 5 to irradiate an elongated first range 402 from the center to the outer circumferential edge of the back surface 102 of the wafer 100 with the laser beam 401 output from the fθ lens 79 as illustrated in FIG. 6.

Then, the first controller 7 rotates the holding table 5 as illustrated by an arrow 501. Due to this, the whole of the back surface 102 that is the ground surface of the wafer 100 is irradiated with the laser beam 401 from the fθ lens 79 of the first laser beam irradiation unit 40, and the whole of the back surface 102 melts. In the present embodiment, because the laser beam 401 with a wavelength having absorbability with respect to the wafer 100 is used, not only the back surface 102 but also a part from the back surface 102 to a predetermined thickness (back surface vicinity part) is also melted. The back surface vicinity part to be melted, which differs depending on the occurrence situation of damage, is a part from the back surface 102 to a thickness of 0.5 to 1.5 μm or approximately 0.5 to 4 μm, for example.

Thereafter, the first controller 7 stops the irradiation with the laser beam 401. Due to this, the back surface 102 and the back surface vicinity part that are melted are cooled and solidified.

(4) Cleaning Step

After the energy supply step, the first controller 7 conveys the wafer 100 to the first cleaning unit 156 by the carrying-out unit 154 illustrated in FIG. 1 and cleans the wafer 100. The first controller 7 carries in the cleaned wafer 100 to the first cassette 150 or the second cassette 151 by the robot hand 155.

As above, in the present embodiment, after the grinding step, the energy supply step is executed to irradiate the back surface 102 that is the ground surface of the wafer 100 ground by the first rough grinding unit 30 and the first finish grinding unit 31 with the laser beam and melt the back surface 102 and the back surface vicinity part including damage caused due to the grinding. Moreover, thereafter, the back surface 102 and the back surface vicinity part are cooled and solidified.

By such a process of melting and cooling for the back surface 102 of the wafer 100, in the present embodiment, crystal growth of the melted region of the back surface 102 and the back surface vicinity part is caused to form seed crystals, and thereafter recrystallization can be caused. Therefore, the back surface 102 can be planarized. In addition, cracks, chips, and so forth caused in the back surface 102 and the back surface vicinity part due to grinding can be eliminated through joining of crystals. Thus, it becomes possible to repair at least part of the damage of the back surface 102 and the back surface vicinity part. Furthermore, the flexural strength of the wafer 100 can be enhanced through the planarization. Therefore, the risk of occurrence of breakage or chipping in the wafer 100 in steps after the energy supply step is alleviated. In addition, the flexural strength of chips can be enhanced when the wafer 100 is turned to the chips.

Here, it is also conceivable that the ground surface is polished by a polishing pad (chemical mechanical polishing (CMP) or dry polishing) for a treatment (planarization and repair of damage) of the ground surface. However, the CMP is a treatment using a chemical, and a configuration for treating the chemical that is a liquid is required. Moreover, part of the ground surface is removed in the CMP polishing and the dry polishing. Therefore, polishing dust is generated and there are possibilities that the polishing dust adheres to the workpiece and that the polishing dust contaminates the inside of the apparatus. In contrast, in the treatment of melting the wafer 100 by the first laser beam irradiation unit 40 to remove damage, the liquid treatment is unnecessary and processing dust is not generated. Thus, the facility can be simplified and contamination of the workpiece and the apparatus can be suppressed.

Furthermore, in the present embodiment, the grinding apparatus 1 includes the first rough grinding unit 30, the first finish grinding unit 31, and the first laser beam irradiation unit 40 over one apparatus base 10 and conveys the wafer 100 from the first rough grinding unit 30 and the first finish grinding unit 31 to the first laser beam irradiation unit 40 by the turntable 6. Thus, in the one grinding apparatus 1, the wafer 100 can be ground by the first rough grinding unit 30 and the first finish grinding unit 31 and damage of the wafer 100 caused due to the grinding can be repaired easily and rapidly by the first laser beam irradiation unit 40. Therefore, it is possible to execute the grinding of the wafer 100 and the repair of the damage efficiently and favorably.

In the present embodiment, it is preferable that the material of the wafer 100 as a workpiece be a material that makes liquid phase growth, such as Si, Ge, or GaAs. The material that makes liquid phase growth readily melts when receiving energy supply through irradiation with a laser beam or the like. Thus, damage formed in the ground surface of the wafer 100 can be favorably repaired by energy supply such as irradiation with a laser beam.

Moreover, in the above-described embodiment, the first laser beam irradiation unit 40 has a configuration using the resonant scanner 77 in order to reciprocate the irradiation position of the laser beam along the Y-axis direction. Instead of this, the first laser beam irradiation unit 40 may reciprocate the irradiation position of the laser beam along the Y-axis direction by using a galvano scanner.

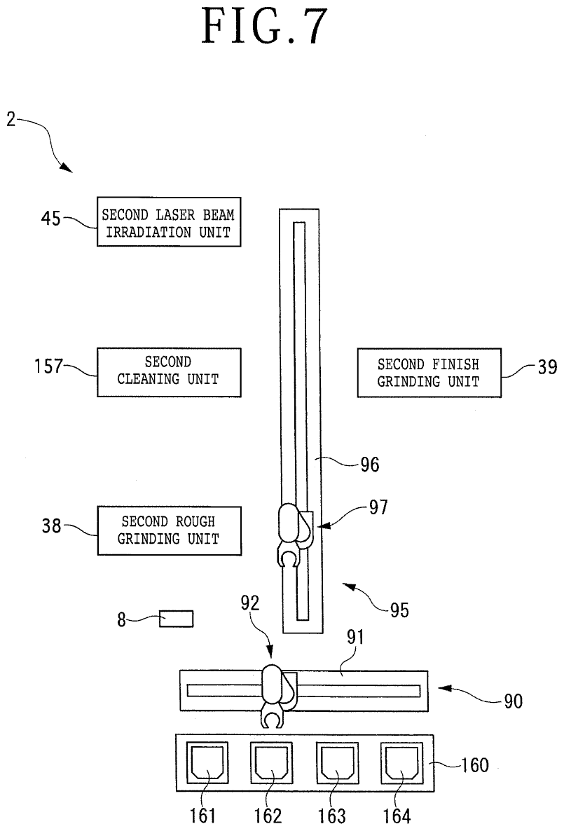

Furthermore, in the above-described embodiment, explanation has been made about the grinding apparatus 1 including the first rough grinding unit 30, the first finish grinding unit 31, and the first laser beam irradiation unit 40 over the one apparatus base 10. However, the configuration is not limited thereto and the first rough grinding unit 30, the first finish grinding unit 31, and the first laser beam irradiation unit 40 may be configured as separate apparatus. In this case, a processing system 2 like one illustrated in FIG. 7 may be employed.

As illustrated in FIG. 7, the processing system 2 has a second rough grinding unit 38 that executes rough grinding of the wafer 100, a second finish grinding unit 39 that executes finish grinding of the wafer 100, a second laser beam irradiation unit 45 that irradiates the wafer 100 with a laser beam, a second cleaning unit 157 that cleans the wafer 100, a cassette placement unit 160, and a first conveying unit 90 and a second conveying unit 95 that convey the wafer 100. Moreover, the processing system 2 includes a second controller 8 that controls the respective components of the processing system 2.

The second rough grinding unit 38 and the second finish grinding unit 39 include a holding mechanism (holding table or the like) that holds the wafer 100, and have functions similar to those of the above-described first rough grinding unit 30 and first finish grinding unit 31 and are configured to execute rough grinding and finish grinding, respectively, of the back surface 102 of the wafer 100.

Furthermore, the second laser beam irradiation unit 45 also includes a holding mechanism that holds the wafer 100. In addition, the second laser beam irradiation unit 45 has functions similar to those of the above-described first laser beam irradiation unit 40, and irradiates a ground surface of the wafer 100 with the laser beam and melts the ground surface to repair at least part of damage caused due to the grinding. The second laser beam irradiation unit 45 is also one example of the energy supply unit similarly to the first laser beam irradiation unit 40.

Moreover, the second cleaning unit 157 is also what cleans the wafer 100 similarly to the first cleaning unit 156. Furthermore, the cassette placement unit 160 has third to sixth cassettes 161 to 164 that house the wafers 100.

The first conveying unit 90 includes a first guide rail 91 extending substantially in parallel to the direction in which the third to sixth cassettes 161 to 164 line up and a first robot 92 that can move along the first guide rail 91. In the first conveying unit 90, taking-out and housing of the wafer 100 from and in the third to sixth cassettes 161 to 164 can be executed by the first robot 92. In the first conveying unit 90, the first robot 92 places the wafer 100 taken out from any of the third to sixth cassettes 161 to 164 over a position adjustment unit that is not illustrated, for example.

The second conveying unit 95 includes a second guide rail 96 and a second robot 97 that can move along the second guide rail 96. The second guide rail 96 extends substantially in parallel to the direction in which the second rough grinding unit 38, the second cleaning unit 157, and the second laser beam irradiation unit 45 line up, and is disposed between them and the second finish grinding unit 39.

In the second conveying unit 95, the wafer 100 placed over the position adjustment unit (not illustrated) by the first robot 92 of the first conveying unit 90 can be held by the second robot 97. Moreover, in the second conveying unit 95, the wafer 100 can be conveyed by the second robot 97 among the second rough grinding unit 38, the second finish grinding unit 39, the second laser beam irradiation unit 45, and the second cleaning unit 157. That is, the second conveying unit 95 can convey the wafer 100 from the second rough grinding unit 38 and the second finish grinding unit 39 to the second laser beam irradiation unit 45.

In the processing system 2 having such a configuration, the second controller 8 that controls the processing system 2 takes out the wafer 100 from any of the third to sixth cassettes 161 to 164 by the first conveying unit 90 and causes the second robot 97 of the second conveying unit 95 to hold the wafer 100 through the position adjustment unit that is not illustrated. Then, the second controller 8 executes the above-described grinding step, energy supply step, and cleaning step for the wafer 100 while moving the wafer 100 among the second rough grinding unit 38, the second finish grinding unit 39, the second laser beam irradiation unit 45, and the second cleaning unit 157 by the second conveying unit 95.

Also in such a processing system 2, similarly to the grinding apparatus 1, by a process of melting by the second laser beam irradiation unit 45 and cooling for the back surface 102 that is the ground surface of the wafer 100, the back surface 102 can be planarized and at least part of damage of the back surface 102 and the back surface vicinity part can be repaired.

Furthermore, also in the processing system 2, the wafer 100 can be conveyed from the second rough grinding unit 38 and the second finish grinding unit 39 to the second laser beam irradiation unit 45 by the second conveying unit 95. Thus, in the one processing system 2, the wafer 100 can be ground by the second rough grinding unit 38 and the second finish grinding unit 39 and damage of the wafer 100 caused due to the grinding can be repaired easily and rapidly by the second laser beam irradiation unit 45. Therefore, it is possible to execute the grinding of the wafer 100 and the repair of the damage efficiently and favorably.

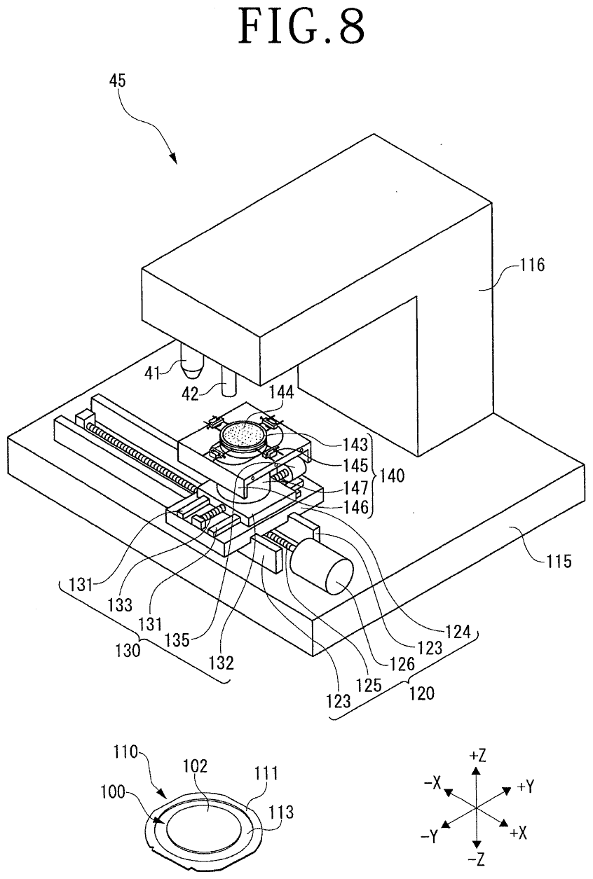

Moreover, in the processing system 2, it is possible to use a configuration like one illustrated in FIG. 8 as the second laser beam irradiation unit 45. In the case of using the second laser beam irradiation unit 45 illustrated in FIG. 8, in the processing system 2, the wafer 100 is treated as a work set 110 including a ring frame 111, an adhesive tape 113, and the wafer 100, for example.

The second laser beam irradiation unit 45 illustrated in FIG. 8 includes a base 115 and includes, over the upper surface of the base 115, a holding table part 140 including a holding table 143, an X-axis movement mechanism 120 that moves the holding table 143 in the X-axis direction, and a Y-axis movement mechanism 130 that moves the holding table 143 in the Y-axis direction.

The X-axis movement mechanism 120 moves the holding table 143 in the X-axis direction relative to the processing head 41. The X-axis movement mechanism 120 includes a pair of guide rails 123 extending in the X-axis direction, an X-axis table 124 placed on the guide rails 123, a ball screw 125 extending in parallel to the guide rails 123, and a drive motor 126 that rotates the ball screw 125.

The pair of guide rails 123 are disposed in parallel to the X-axis direction on the upper surface of the base 115. The X-axis table 124 is installed on the pair of guide rails 123 slidably along these guide rails 123. The Y-axis movement mechanism 130 and the holding table part 140 are placed over the X-axis table 124.

The ball screw 125 is screwed to a nut part (not illustrated) disposed on the X-axis table 124. The drive motor 126 is coupled to one end part of the ball screw 125 and rotationally drives the ball screw 125. Through the rotational driving of the ball screw 125, the X-axis table 124, the Y-axis movement mechanism 130, and the holding table part 140 move in the X-axis direction along the guide rails 123.

The Y-axis movement mechanism 130 moves the holding table 143 in the Y-axis direction relative to the processing head 41. The Y-axis movement mechanism 130 includes a pair of guide rails 131 extending in the Y-axis direction, a Y-axis table 132 placed on the guide rails 131, a ball screw 133 extending in parallel to the guide rails 131, and a drive motor 135 that rotates the ball screw 133.

The pair of guide rails 131 are disposed in parallel to the Y-axis direction on the upper surface of the X-axis table 124. The Y-axis table 132 is installed on the pair of guide rails 131 slidably along these guide rails 131. The holding table part 140 is placed over the Y-axis table 132.

The ball screw 133 is screwed to a nut part (not illustrated) disposed on the Y-axis table 132. The drive motor 135 is coupled to one end part of the ball screw 133 and rotationally drives the ball screw 133. Through the rotational driving of the ball screw 133, the Y-axis table 132 and the holding table part 140 move in the Y-axis direction along the guide rails 131.

The holding table part 140 has the holding table 143 that holds the wafer 100, clamp parts 145 disposed around the holding table 143, a support column 147 that supports the holding table 143, and a cover plate 146 disposed on the upper end of the support column 147 to surround the holding table 143.

A holding surface 144 composed of a porous material is formed in the upper surface of the holding table 143. The holding surface 144 can suck and hold the wafer 100 in the work set 110 by being caused to communicate with a suction source (not illustrated).

Four clamp parts 145 are disposed around the holding table 143. The four clamp parts 145 clamp and fix, from four sides, the ring frame 111 around the wafer 100 held by the holding table 143.

Furthermore, the second laser beam irradiation unit 45 includes a housing 116 that is installed on the base 115 and has the processing head 41 and the camera 42.

In the housing 116, for example, the laser oscillator 75, the X-axis direction disperser 76, the second mirror 78, and the resonant scanner 77 illustrated in FIG. 5, and so forth, are incorporated. In addition, the processing head 41 has the fθ lens 79 illustrated in FIG. 5. Due to this, in the second laser beam irradiation unit 45, a laser beam with a wavelength having absorbability with respect to the wafer 100 held by the holding table 143 of the holding table part 140 can be emitted similarly to the first laser beam irradiation unit 40.

In the processing system 2 including the second laser beam irradiation unit 45 having such a configuration, the second controller 8 causes emission of the laser beam from the laser oscillator 75 illustrated in FIG. 5 to irradiate the back surface 102 of the wafer 100 held by the holding table 143 with the laser beam 401 from the fθ lens 79 of the processing head 41.

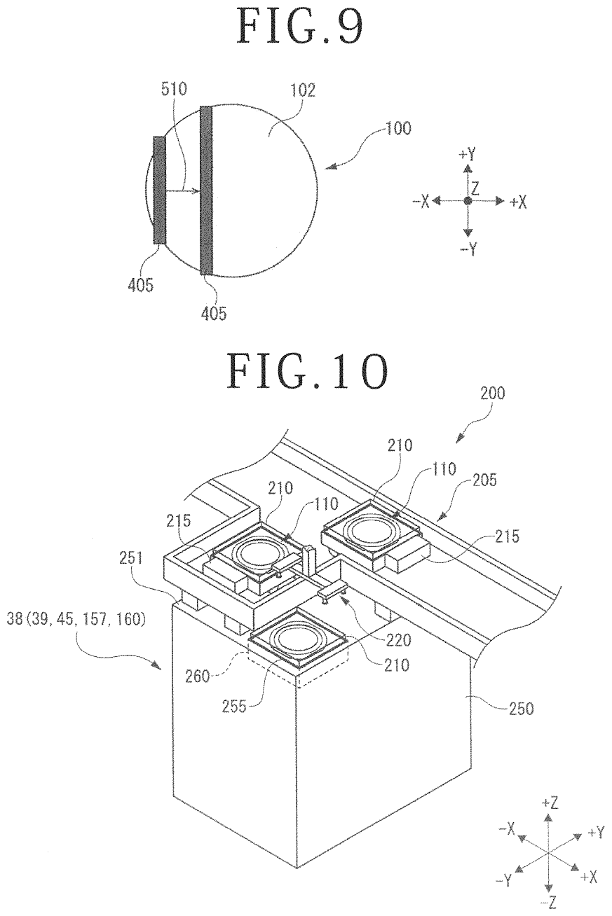

At this time, as illustrated in FIG. 9, the second controller 8 controls the X-axis movement mechanism 120 to irradiate an end part on the −X side in the back surface 102 of the wafer 100 with the laser beam 401. At this time, the second controller 8 sets the irradiation range of the laser beam 401 to a first range 405 longer than the length of the wafer 100 in the Y-axis direction by controlling the swing state of the swing mirror 771 in the resonant scanner 77.

Moreover, the second controller 8 controls the X-axis movement mechanism 120 (see FIG. 8) to move the holding table 143 that holds the wafer 100 in the −X direction. The causes the first range 405 to relatively move in the +X direction on the back surface 102 of the wafer 100 as illustrated by an arrow 510 in FIG. 9. At this time, the length of the first range 405 that is the irradiation range of the laser beam 401 is set as appropriate to become longer than the length in the Y-axis direction regarding the wafer 100 at the part at which the first range 405 is located.

In this manner, the whole of the back surface 102 that is the ground surface of the wafer 100 is irradiated with the laser beam 401 from the fθ lens 79 of the second laser beam irradiation unit 45 and the whole of the back surface 102 melts. Due to this, the back surface 102 is planarized and at least part of damage of the back surface 102 and the back surface vicinity part is repaired.

The length of the first range 405 may be set longer than the diameter of the wafer 100 irrespective of the position of the first range 405 in the wafer 100.

Furthermore, the processing system 2 illustrated in FIG. 7 may have a conveying system 200 like one illustrated in FIG. 10 instead of the first conveying unit 90 and the second conveying unit 95.

The conveying system 200 is one example of the conveying unit and includes a traveling rail 205. The traveling rail 205 is installed to extend to the second rough grinding unit 38, the second finish grinding unit 39, the second laser beam irradiation unit 45, the second cleaning unit 157, and the cassette placement unit 160 illustrated in FIG. 7, and so forth, so that the wafer 100 can be conveyed to these units. That is, these units are coupled to each other through the traveling rail 205. In addition, the traveling rail 205 is disposed above casings 250 of these units as illustrated in FIG. 10.

Moreover, the conveying system 200 includes trays 210 that house the work set 110 including the wafer 100 and automatic conveying vehicles 215 that convey the tray 210. The automatic conveying vehicle 215 can convey the work set 110 including the wafer 100 between the respective units by traveling on the traveling rail 205 in the state in which the automatic conveying vehicle 215 holds the tray 210 that houses the work set 110. That is, the conveying system 200 conveys the wafer 100 from the second rough grinding unit 38 and the second finish grinding unit 39 to the second laser beam irradiation unit 45 by the automatic conveying vehicle 215.

An opening 255 is made at a corner part of a top plate 251 of the casing 250 of each unit. Furthermore, a tray support base 260 for supporting the tray 210 is disposed in the casing 250. The tray support base 260 is raised and lowered by a raising-lowering mechanism (not illustrated) to pass through the opening 255 in the state in which it supports the tray 210.

Moreover, the conveying system 200 has a tray conveying arm 220 near the opening 255. The tray conveying arm 220 conveys the tray 210 between the tray support base 260 positioned to a height equivalent to that of the opening 255 and the automatic conveying vehicle 215 that has stopped near the opening 255.

Therefore, it is possible to carry in the work set 110 including the wafer 100 to the inside of the casing 250 by stopping the automatic conveying vehicle 215 that holds the tray 210 housing the work set 110 near the casing 250 of each unit and transferring the tray 210 to the tray support base 260 of the casing 250 by the tray conveying arm 220 and lowering the tray support base 260 by the raising-lowering mechanism that is not illustrated.

Furthermore, it is possible to convey the work set 110 to another unit by housing, in the tray 210, the work set 110 including the wafer 100 resulting from processing in the casing 250 of each unit and supporting the tray 210 by the tray support base 260 and raising the tray support base 260 to the opening 255 by the raising-lowering mechanism to transfer the tray 210 to the automatic conveying vehicle 215 by the tray conveying arm 220.

In the case of using such a conveying system 200, the second controller 8 executes the above-described grinding step, energy supply step, and cleaning step for the wafer 100 while moving the wafer 100 among the second rough grinding unit 38, the second finish grinding unit 39, the second laser beam irradiation unit 45, the second cleaning unit 157, and the cassette placement unit 160 by the conveying system 200.

Therefore, also in this case, by laser irradiation for the back surface 102 that is the ground surface of the wafer 100 by the second laser beam irradiation unit 45, the back surface 102 is planarized and at least part of damage of the back surface 102 and the back surface vicinity part is repaired.

Moreover, by the conveying system 200, the wafer 100 can be conveyed from the second rough grinding unit 38 and the second finish grinding unit 39 to the second laser beam irradiation unit 45. Thus, in the one processing system 2, the wafer 100 can be ground by the second rough grinding unit 38 and the second finish grinding unit 39 and damage of the wafer 100 caused due to the grinding can be repaired easily and rapidly by the second laser beam irradiation unit 45. Therefore, it is possible to execute the grinding of the wafer 100 and the repair of the damage efficiently and favorably.

Furthermore, as described above, the laser oscillator 75 of the first laser beam irradiation unit 40 illustrated in FIG. 5 emits the laser beam with a wavelength having absorbability with respect to the wafer 100. For example, when the wafer 100 is a silicon wafer, the wavelength of the laser beam emitted from the laser oscillator 75 is a wavelength in a range of 500 to 1000 nm, which is a wavelength having absorbability with respect to silicon.

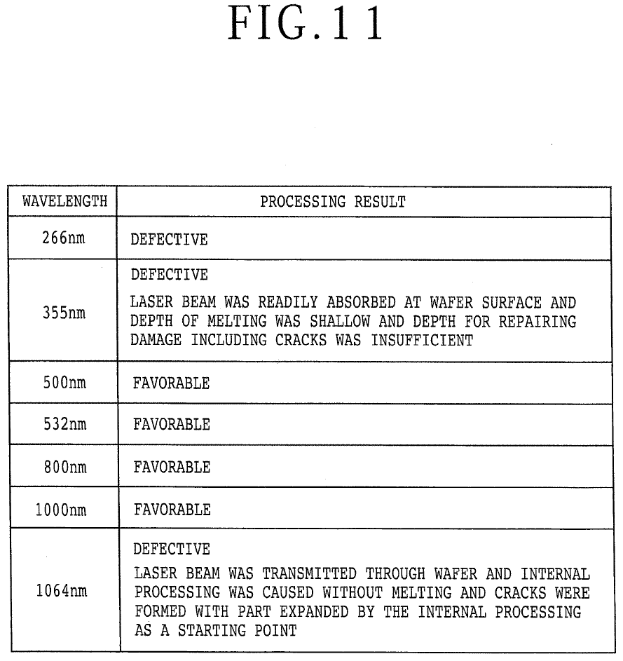

FIG. 11 is a diagram illustrating a table indicating a relation between the wavelength of the laser beam emitted from the laser oscillator 75 and the result (processing result) of the energy supply step executed by using each laser beam. As illustrated in this table, when the wavelength fell within a range of 500 to 1000 nm, it was possible to favorably melt the back surface 102 that was the ground surface of the wafer 100 that was a silicon wafer and the back surface vicinity part.

On the other hand, when the wavelength was equal to or shorter than 355 nm, it was difficult to sufficiently melt the back surface 102 that was the ground surface of the wafer 100 that was a silicon wafer and the back surface vicinity part. Furthermore, also when the wavelength was 1064 nm, it was difficult to favorably melt the back surface 102 and the back surface vicinity part because the laser beam was transmitted through the wafer 100.

In the energy supply step, energy may be supplied in any form. For example, instead of irradiation with a laser beam, plasma, an ion beam, electromagnetic waves, or the like may be supplied to a ground surface of a workpiece to melt the ground surface and repair at least part of damage caused due to grinding. When the energy supply unit is a plasma supply apparatus that supplies plasma to a workpiece, for example, the plasma supply apparatus including a vacuum chamber, a holding table that holds the wafer 100 (workpiece) in the vacuum chamber, and a plasma supply unit that supplies a gas in a plasma state to the wafer 100 held by the holding table is used.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing system of a workpiece comprising:
a grinding unit that includes a grinding wheel and a spindle that rotatably supports the grinding wheel, and grinds the workpiece;
an energy supply unit that supplies energy to a ground surface of the workpiece ground by the grinding unit and melts the ground surface to repair at least part of damage caused due to the grinding; and
a conveying unit that conveys the workpiece from the grinding unit to the energy supply unit.

2. The processing system according to claim 1, wherein
the energy supply unit is a laser beam irradiation unit that includes a laser oscillator that emits a laser beam and a condenser lens that condenses the laser beam, and executes irradiation with the laser beam.

3. The processing system according to claim 2, wherein
the laser beam irradiation unit executes irradiation with the laser beam with a wavelength having absorbability with respect to the workpiece.

4. The processing system according to claim 2, wherein
a wavelength of the laser beam is a wavelength in a range of 500 to 1000 nm.

5. The processing system according to claim 1, wherein
a material of the workpiece is a material that makes liquid phase growth.

6. The processing system according to claim 1, wherein
the conveying unit is a turntable that rotatably supports a holding table that holds the workpiece, and
the holding table that holds the workpiece is moved from the grinding unit to the energy supply unit by rotation of the turntable.
